(19) United States
(12) Patent Application Publication
(10) Pub. No.: US 2012/0223313 A1
(43) Pub. Date: Sep. 6, 2012

(54) THIN FILM TRANSISTOR SUBSTRATE AND METHOD FOR MANUFACTURING SAME

(75) Inventor: Tohru Amano, Osaka (JP)

(73) Assignee: SHARP KABUSHIKI KAISHA, Osaka (JP)

(21) Appl. No.: 13/509,361

(22) PCT Filed: Jul. 12, 2010
(86) PCT No.: PCT/JP2010/004514

§ 371 Date: May 11, 2012

(30) Foreign Application Priority Data
Nov. 12, 2009 (JP) 2009-259260

(51) Int. Cl. H01L 33/08

(52) U.S. Cl. 257/59; 438/34; 257/E33.053

(57) ABSTRACT

Disclosed is a thin film transistor substrate which is provided with: a plurality of source lines 11a provided to extend parallel to a substrate 10; a plurality of gate lines 13a provided to extend parallel to each other in the direction that intersects the source lines 11a; and a plurality of pixel electrodes 17a, which are arranged in a matrix along the direction wherein the source lines 11a extend and in the direction wherein the gate lines 13a extend. On each gate line 13a, a through hole Ha is provided at a part where each gate line intersects each source line 11a, and inside of the through hole Ha, a semiconductor layer 15a is provided with a gate insulating film 14a therebetween. Each semiconductor layer 15a exposed from each gate line 13a has one end thereof being overlapped by the source line 11a and connected to the source line 11a, and the other end thereof being overlapped by the drain electrode 16a and connected to the drain electrode 16a, the drain electrodes being electrically connected to the pixel electrodes 17a, respectively.

### TECHNICAL FIELD

The present invention relates to a thin film transistor substrate and a method for the manufacture of such, and the present invention particularly relates to a thin film transistor substrate composing a liquid crystal display panel, as well as a method for the manufacture of such a thin film transistor substrate.

### BACKGROUND ART

A liquid crystal display panel, for example, is equipped with a TFT substrate provided with thin film transistors (referred to hereinafter as TFTs) or the like as switching elements, a CF substrate arranged in an opposing fashion to the TFT substrate and provided with color filters (referred to hereinafter as CFs) or the like, and a liquid crystal layer provided between the TFT substrate and the CF substrate. The liquid crystal display panel is constructed so as to display an image by changing the orientation state of the liquid crystal layer through an applied voltage so as to adjust transmittance of light entering the liquid crystal display panel from a backlight arranged at the exterior.

In the semiconductor layer composing the TFT, a leak current (photocurrent) is generated in the OFF state due to photo-excitation, for example, when light enters from the backlight. This results in an increase of the off-state current of the TFT. Since such an increase results in lowering of display quality of the liquid crystal display panel, the semiconductor layer of the TFT must be sufficiently shielded from light on the TFT substrate.

For example, in Patent Document 1, an active matrix substrate is disclosed that provides a metal layer for light-shielding over the TFT channel layer with an interlayer insulation film therebetween.

### RELATED ART DOCUMENTS

### Patent Documents

Patent Document 1: Japanese Patent Application Laid-Open Publication No. H10-186402

### SUMMARY OF THE INVENTION

### Problems to be Solved by the Invention

FIG. 8 is a top view of a conventional TFT 105, and FIG. 9 is a cross-sectional view of the TFT 105 along the IX-IX line in FIG. 8.

As shown in FIGS. 8 and 9, TFT 105 is equipped with a gate electrode (111) that is part of a gate line 111 provided on the glass substrate 110, a gate insulation film 112 provided so as to cover the gate electrode (111), and a semiconductor layer 113 provided and arranged in an island-shape so as to cover the gate electrode (111) with a gate insulation film 112 therebetween. A source electrode 114a and a drain electrode 114b are provided and opposingly arranged so as to overlap the gate electrode (111). Here, the source electrode 114a, as shown in FIG. 8, is a part that projects laterally from the source line 114 arranged orthogonally with respect to the gate line 111.

For this TFT 105, as shown in FIG. 9, for example, since the ends of the semiconductor layer 113 are exposed from the gate electrode (111) in the same manner as in the active matrix substrate disclosed in Patent Document 1, due to light from the backlight entering the semiconductor layer 113 from the periphery of the gate electrode (111), a photocurrent is generated in the semiconductor layer 113, and there is concern that the off-state current of the TFT 105 may increase.

The present invention was devised in consideration of such factors. An object of the present invention is to suppress the light-induced increase of the off-state current of a thin film transistor.

### Means for Solving the Problems

In order to attain the aforementioned object, the present invention is configured so that the electrical current between the source and the drain (i.e., the channel electrical current) flows along the substrate thickness direction (i.e., not along the substrate surface direction as in the conventional thin film transistor).

Specifically, a thin film transistor substrate of the present invention includes: a plurality of source lines disposed to extend parallel to a substrate; a plurality of gate lines disposed to extend in parallel with each other in a direction that intersects the aforementioned source lines; and a plurality of pixel electrodes arranged in a matrix along the direction of extension of the aforementioned source lines and along the direction of extension of the aforementioned gate lines, wherein, in each aforementioned gate lines, a through hole is provided at an intersection part with each source line so as to penetrate the gate line in a direction of thickness of the substrate; a semiconductor layer is provided on an interior of each of aforementioned through hole with a gate insulation film interposed therebetween; and one end of each of the semiconductor layers exposed from each aforementioned gate line is overlapped by and connected to the corresponding source line, and the other end thereof is overlapped by and is connected to a drain electrode electrically connected to corresponding the pixel electrode.

According to the aforementioned structure, a through hole is provided at the intersection part of each gate line and each source line, and a semiconductor layer is provided at the interior of each through hole with a gate insulation film interposed therebetween. Each semiconductor layer exposed from each gate line has one end connected to each aforementioned source line, and the other end is connected to a drain electrode that is electrically conducting to each pixel electrode. Thus, a thin film transistor is constructed for which the channel electrical current flows along the direction of extension of each through hole of each gate line, i.e., along the substrate thickness direction. Thus, the semiconductor layer of this thin film transistor, in the direction of the substrate surface (along the substrate surface), is surrounded at the interior face of the though hole of the gate line (made of metal that blocks light), and in the substrate thickness direction, the semiconductor layer is overlapped by the source line (made of metal that blocks light) and the drain electrode. Thus, almost none of the light from the backlight or the like enters the semiconductor layer. This way, an increase of off-state current by the thin film transistor due to light is suppressed for the thin film transistor substrate that is provided with a respective thin film transistor at the intersection part of each source line and each gate line.

Moreover, this thin film transistor substrate is formed such that the thin film transistor formed at the intersection part of each source line and each gate line does not protrude from the source line and the gate line, and it is thus possible to increase the aperture ratio of the pixels.

An inner face of each aforementioned through hole may be sloped so that the through hole becomes progressively larger outwardly with increasing distance from a surface of the substrate.

According to the aforementioned structure, the inner face of each through hole is tilted relative to the surface of the substrate so that each through hole becomes progressively larger outwardly with increasing distance from the surface of the substrate. Thus, it becomes possible to manufacture a thin film transistor substrate by etching a metal film to form tapered shape at the edge thereof in at least positions where the through hole is formed so as to form the respective gate lines, and by forming thereafter a gate insulation film so as to cover each gate line.

The angle of the inner face of aforementioned through hole relative to the surface of the aforementioned substrate may be 40° to 50°.

According to the aforementioned structure, the inner face of each through hole is tilted relative to the surface of the substrate at an angle of 40° to 50° so that the through hole becomes progressively larger with increased distance from the surface of the substrate. Therefore, gate insulation film is formed specifically on the inner surface of each through hole of each gate line. Here, when the angle of the inner face of each through hole relative to the surface of the substrate is less than 40°, the size of the thin film transistor may become excessively large. Moreover, when the angle of the inner face of each through hole relative to the surface of the substrate exceeds 50°, there may be decreased ability to form the insulation film for forming the gate insulation film on the inner face of each through hole of each gate line.

A peripheral edge of the aforementioned drain electrode may extend beyond an edge of the through hole in the gate line on a side of the drain electrode.

By use of the aforementioned structure, even when the inner face of each through hole is tilted relative to the surface of the substrate so that each through hole becomes progressively wider outwardly with increasing distance from the surface of the substrate, due to extension of the peripheral edges of the drain electrode (made of a metal that blocks light) beyond the edges of each through hole of each gate line on a side of the drain electrode, light from the backlight or the like is unlikely to enter the semiconductor layer.

An inner face of each aforementioned through hole may be perpendicular to a surface of the aforementioned substrate.

Due to the aforementioned structure, the inner face of each through hole is perpendicular to surface of the substrate, and thus, for example, it becomes possible to manufacture a thin film transistor substrate by etching a metal film to have an erect shaped edge in forming each gate line, forming an insulation film so as to bury each through hole of each gate line and to cover each gate line, and by thereafter patterning the insulation film to form the gate insulation film.

Moreover, because the inner face of each through hole is perpendicular to the surface of the substrate, the size of the thin film transistor becomes smaller than the case where the inner face of each through hole was tilted relative to the surface of the substrate, and therefore, it becomes possible to further improve the aperture ratio of the pixels.

Moreover, a method for manufacturing a thin film transistor substrate that includes: a plurality of source lines disposed to extend in parallel with each other; a plurality of gate lines disposed to extend parallel to each other in a direction that intersects the source lines; and a plurality of pixel electrodes disposed in a matrix along the direction of extension of the source lines and along the direction of extension of the gate lines, the method including: a source line formation process that includes forming a first metal film on the substrate and thereafter patterning the first metal film to form the plurality of source lines; a first gate insulation film formation process that includes forming a first insulation film so as to cover each source line formed in the source line formation process, and thereafter patterning the first insulation film so as to expose at least part of the intersection of the source line and the gate line to form a first gate insulation film; a gate line formation process that includes forming a second metal film to cover the first gate insulation film formed in the first gate insulation film formation process, and thereafter patterning the second metal film so as to expose a part of the source line that has been exposed from the first gate insulation film to form the plurality of gate lines having a through hole arranged in the exposed part of each source line; a second gate insulation film formation process that includes forming a second insulation film to cover the gate line formed in the gate line formation process, and thereafter patterning the second insulation film so as to expose at least a part of the exposed part of the source line within an interior of the through hole of each gate line to form a second gate insulation film; a semiconductor layer formation process that includes forming a semiconductor film so as to cover the second gate insulation film formed in the second gate insulation film formation process, and thereafter patterning the semiconductor film to form a semiconductor layer in the interior of each through hole of each gate line; a drain electrode formation process that includes forming a third metal film so as to cover each semiconductor layer formed in the semiconductor layer formation process, and thereafter patterning the third metal film to form a plurality of drain electrodes so as to overlap corresponding the semiconductor layer; and a pixel electrode formation process that includes forming a transparent electrically conductive film so as to cover each drain electrode formed in the drain electrode formation process, and thereafter patterning the transparent electrically conductive film to form the plurality of pixel electrodes so as to overlap corresponding the drain electrode.

According to the aforementioned method, in the first gate insulation film process, a first gate insulation film is formed to provide electrical insulation between each gate line formed in the gate line formation process and each source line formed in the source line formation process. In the gate line formation process, a plurality of gate lines are formed, each with a through hole arranged at the intersection with each source line formed in the source line formation process. In the second gate insulation film formation process, the second gate insulation film is formed to provide electrical insulation between the drain electrode to be formed in the drain electrode formation process as well as the semiconductor layer to be formed during the semiconductor layer formation process and each gate line formed in the gate line formation process. In the semiconductor layer formation process, a semiconductor layer is formed so as to be connected to the corresponding source line formed in the source line formation process. In the drain electrode formation, a drain electrode is formed to connect the pixel electrode to be formed in the pixel electrode formation process to the semiconductor layer formed in the semiconductor layer formation process. Thus, a semiconductor layer is provided at the interior of each through hole of each gate line with a second gate insulator film interposed therebetween, one end of each semiconductor layer exposed from each gate line is connected to the corresponding source line, and the other end is connected to the drain electrode that is electrically connected to the corresponding pixel electrode. Thus, there is manufactured a thin film transistor in which the channel electrical current flows along the direction of extension of each through hole of each gate line, i.e., along the thickness direction of the substrate. Also, in this thin film transistor, the semiconductor layer is surrounded by the inner faces of the through hole in the gate line (made of a metal that can block light) in the substrate surface direction (along the substrate surface), and in the substrate thickness direction, the semiconductor layer is overlapped by the drain electrode and the source line (constructed from metal capable of blocking light) so that there is almost no entry into the semiconductor layer of light from the backlight or the like. This way, the increase of off-state current of the thin film transistor due to light is suppressed in the thin film transistor substrate provided with this thin film transistor at each respective intersection of each source line and each gate line.

In the aforementioned gate line formation process, the aforementioned second metal film may be patterned so that an inner face of each aforementioned through hole is tilted relative to a surface of the aforementioned substrate so that each aforementioned through hole becomes progressively larger outwardly with increasing distance from the surface of the aforementioned substrate.

Due to the aforementioned method, each gate line in the gate line formation process is formed by patterning the second metal film such that the inner face of each through hole tilts relative to the surface of the substrate so that each through hole becomes progressively larger with increasing distance from the surface of the substrate. Thus, a thin film transistor substrate that is provided with thin film transistors in which the channel electrical current flows along the direction of the substrate thickness can be concretely manufactured.

In the aforementioned gate line formation process, the aforementioned second metal film may be patterned so that an inner face of each aforementioned through hole is perpendicular to a surface of the aforementioned substrate, and in the aforementioned second gate insulation film formation process, after forming the aforementioned second insulation film so as to bury each through hole of each aforementioned gate line, the aforementioned second insulation film may be patterned.

By use of the aforementioned method, in the gate line formation process, the second metal film is patterned so that the inner face of each through hole is perpendicular to the surface of the substrate to form each gate line. In the second gate insulation film formation process, the second insulation film is formed so as to bury each through hole of each gate line, and thereafter the second insulation film is patterned to form the second gate insulation film. Thus, a thin film transistor substrate that is equipped with a thin film transistor in which the channel electrical current flows along the direction of substrate thickness can be concretely manufactured.

### Effects of the Invention

According to the present invention, a thin film transistor is constructed such that the channel electrical current flows in the substrate thickness direction, and it is thus possible to suppress a light-induced increase of off-state current of the thin film transistor.

### BRIEF DESCRIPTION OF THE DRAWINGS

FIG. 1 is a top view of a TFT substrate 20 according to a first embodiment.

FIG. 2 is a cross-sectional view of the TFT substrate 20 along the II-II line in FIG. 1.

FIG. 3 is a cross-sectional view of the first half of the manufacturing process of the TFT substrate 20.

FIG. 4 is a cross-sectional view of the latter half of the manufacturing process of the TFT substrate 20.

FIG. 5 is a cross-sectional view of a TFT substrate 30 according to a second embodiment.

FIG. 6 is a cross-sectional view of the first half of the manufacturing process of the TFT substrate 30.

FIG. 7 is a cross-sectional view of the latter half of the manufacturing process of the TFT substrate 30.

FIG. 8 is a top view of a conventional TFT 105.

FIG. 9 is a cross-sectional drawing of the TFT 105 along the IX-IX line within FIG. 8.

### DETAILED DESCRIPTION OF EMBODIMENTS

Embodiments of the present invention are described in detail below based on drawings. The present invention is not limited to the various embodiments described below.

### First Embodiment of the Invention

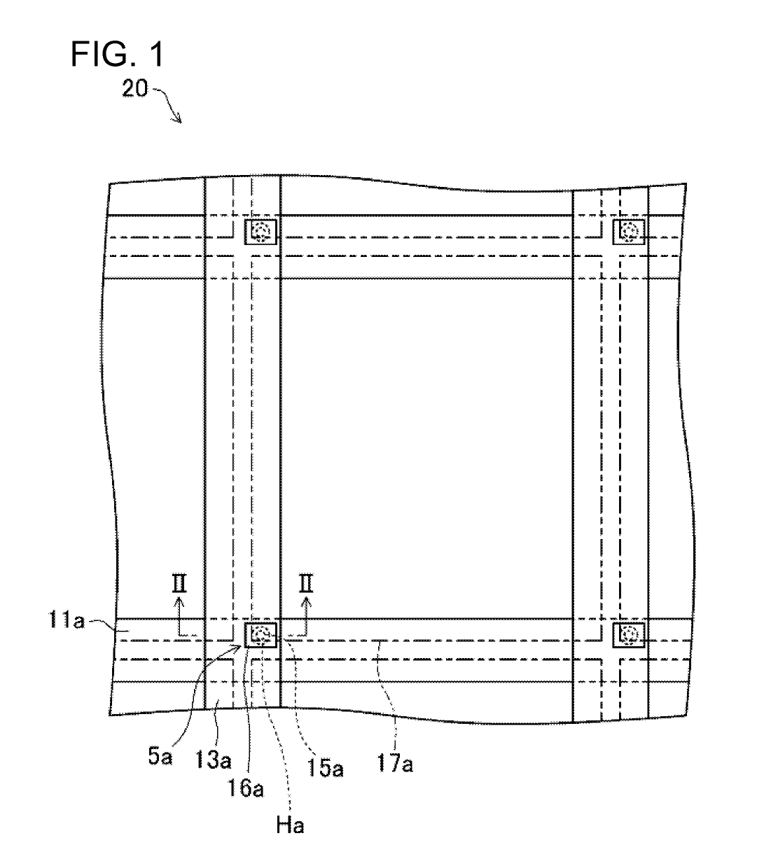

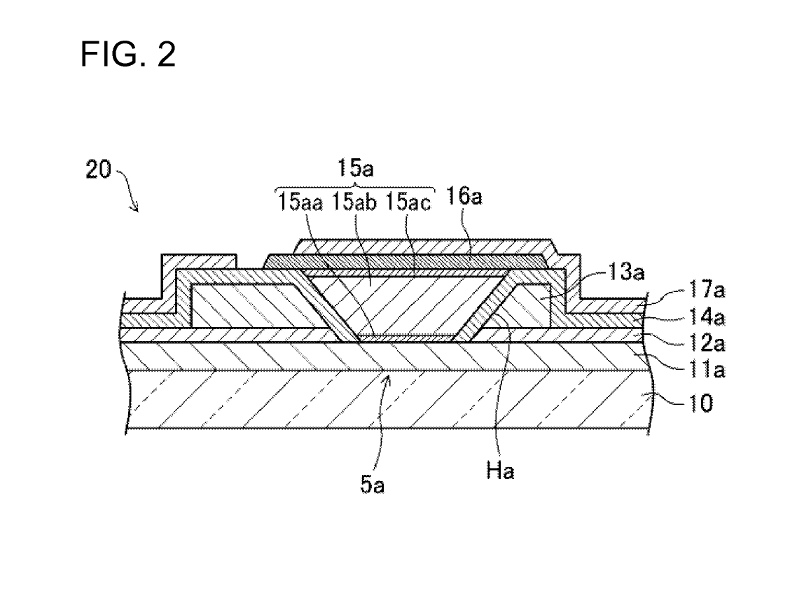

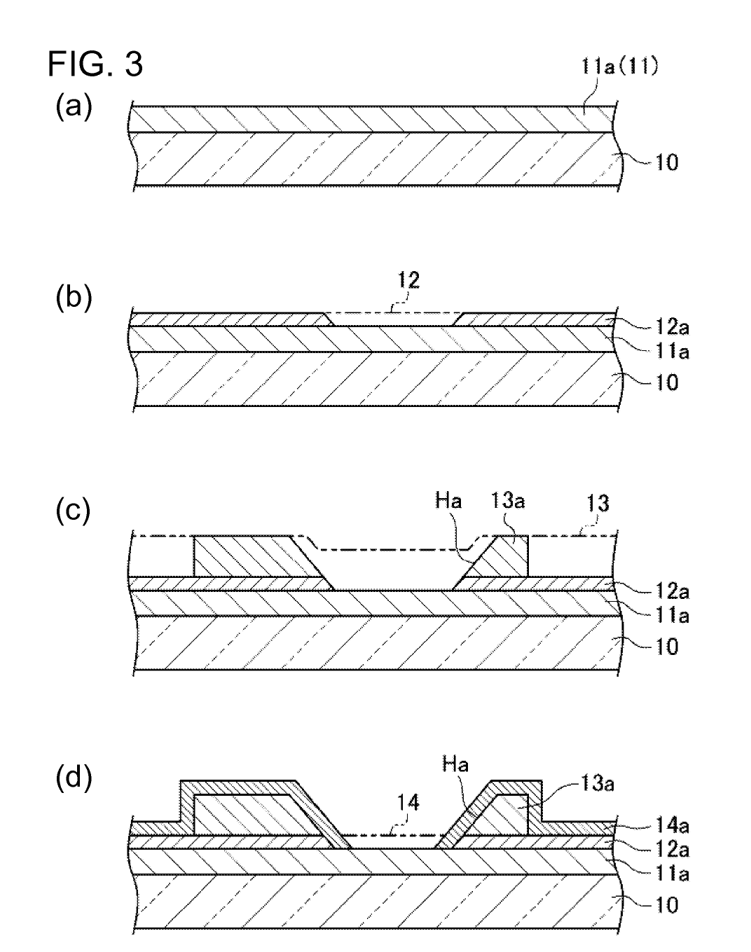

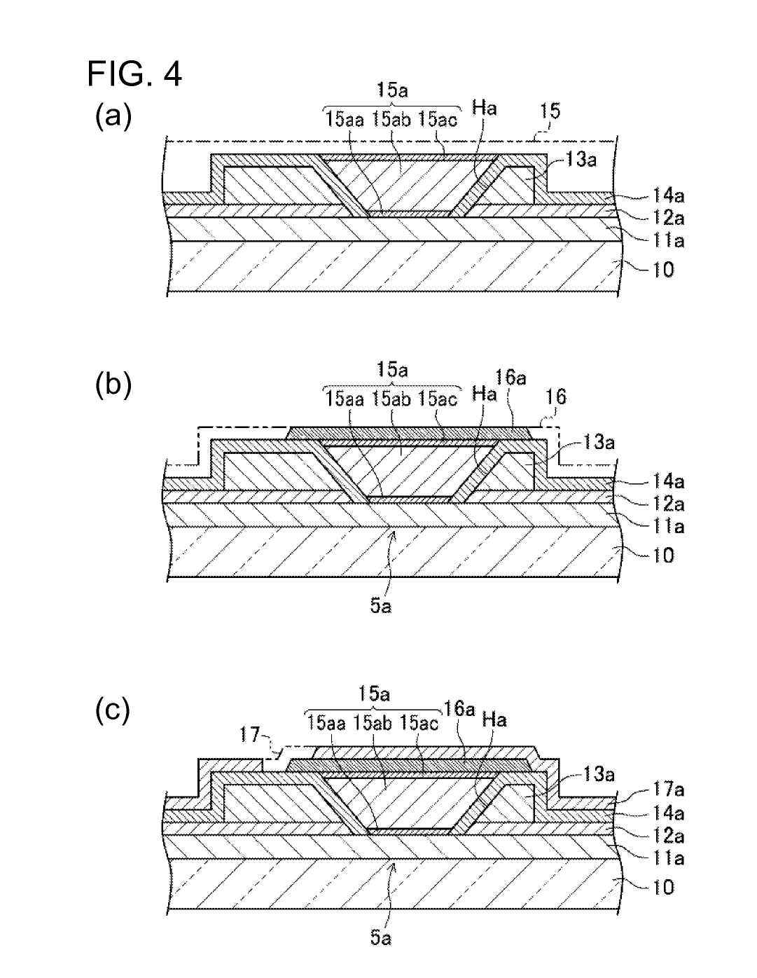

FIGS. 1 to 4 show a first embodiment of the present invention and show a thin film transistor substrate and a manufacturing method for this thin film transistor substrate. Specifically, FIG. 1 is a top view of the TFT substrate 20 of the present embodiment, and FIG. 2 is a cross-sectional drawing of the TFT substrate 20 at the II-II line within FIG. 1. Moreover, FIGS. 3 and 4 are cross-sectional drawings that show the manufacturing process of the TFT substrate 20 shown in FIG. 2. Within FIG. 1, a pixel electrode 17a arranged on the uppermost layer of the TFT substrate 20 of FIG. 2 is indicated by alternate long and two short dash lines.

As shown in FIGS. 1 and 2, the TFT substrate 20 is provided with: an insulating substrate 10, a plurality of source lines 11a arranged so as to extend parallel to one another on the insulating substrate 10, a plurality of gate lines 13a arranged so as to extend parallel to one another in a direction that intersects the respective source lines 11a, a plurality of TFTs 5a that are respectively arranged at the respective intersections of the source line 11a and the gate line 13a, a plurality of pixel electrodes 17a that are respectively connected to the respective TFT 5a and that are provided in a matrix pattern extending along the direction of extension of the source lines 11a and along the direction of extension of the gate lines 13a, and an alignment film (not illustrated) arranged so as to cover each pixel electrode 17a.

The gate line 13a, as shown in FIGS. 1 and 2, has a through hole Ha that penetrates in the thickness direction of the insulating substrate 10 at the intersection with the respective source lines 11a. Here, the through hole Ha, as shown in FIG. 2, has an inner face that is titled by 40° to 50° relative to the surface of the insulating substrate 10 such that diameter widens with increased distance from the surface of the insulating substrate 10. As shown in FIG. 1, the through hole Ha of the present embodiment has a circular shape as viewed from above. However, this shape is exemplary, and the shape as viewed from above may be polygonal or elliptical.

As shown in FIG. 2, TFT 5a is provided with a funnel-shaped gate electrode 13a that is an interior face part of each respective through hole Ha of the gate line 13a, a first gate insulation film 12a that electrically insulates the source line 11a and the gate line (gate electrode) 13a, a second gate insulation film 14a arranged so as to cover the gate electrode 13a, a semiconductor layer 15a provided in the interior of each respective through hole Ha (i.e., in the concave part of the second gate insulation film 14a), a source electrode (11a) that is part of the source line 11a connected to one end (downward end in the figure) of the semiconductor layer 15a exposed from the gate line (gate electrode) 13a, and a drain electrode 16a connected to the other end (upper end in the figure) of the semiconductor layer 15a exposed from the gate line (gate electrode) 13a.

As shown in FIG. 2, the semiconductor layer 15a includes an N+ amorphous silicon layer 15aa connected to the source line (source electrode) 11a, an N+ amorphous silicon layer 15ac connected to the drain electrode 16a, and an intrinsic amorphous silicon layer 15ab provided between the N+ amorphous silicon layer 15aa and the N+ amorphous silicon layer 15ac.

As shown in FIGS. 1 and 2, the source line (source electrode) 11a is arranged so as to overlap the semiconductor layer 15a.

As shown in FIGS. 1 and 2, the peripheral end of the drain electrode 16a protrudes farther than the edge of the respective through hole Ha of the gate line 13a, and is provided so as to overlap the semiconductor layer 15a. Moreover, as shown in FIGS. 1 and 2, the pixel electrode 17a is arranged upon the drain electrode 16a.

The TFT substrate 20 of the aforementioned structure constitutes an active matrix drive type liquid crystal display panel together with a CF substrate (not illustrated) disposed facing the TFT substrate 20 and a liquid crystal layer (not illustrated) sealed between both of these substrates.

Next, a method of manufacturing the TFT substrate 20 of the present embodiment will be described using FIGS. 3 and 4. The method of manufacture of the present invention includes a source line formation process, a first gate insulation film formation process, a gate line formation process, a second gate insulation film formation process, a semiconductor layer formation process, a drain electrode formation process, and a pixel electrode formation process.

Source Line Formation Process

As shown in FIG. 3(a), the sputtering method, for example, is used to form a metal film 11 by depositing a titanium film (about 500 Angstroms thick) and an aluminum film (about 3,000 Angstroms thick), or the like in that order on the entire insulating substrate 10 (i.e., glass substrate or the like). Thereafter, photolithography is used to pattern the first metal film 11 to form multiple source lines 11a. A method of directly forming each source line 11a on the insulation substrate 10 is as an example in the present embodiment, although a base coat film may be formed between the insulating substrate 10 and each source line 11a.

First Gate Insulation Film Formation Process

As shown in FIG. 3(b), by plasma chemical vapor deposition (CVD), for example, a first insulation film 12 of silicon nitride (about 1,500 Angstroms thickness) or the like is formed on the entire substrate onto which the multiple source lines 11a have been formed in the aforementioned source line formation process. Thereafter, photolithography is used to form the first gate insulation film 12a by patterning the first insulation film 12 so that at least part of the (anticipated) intersection between the respective source line 11a and the respective gate line 13a is exposed.

Gate Line Formation Process

As shown in FIG. 3(c), by a sputtering method, for example, a second metal film 13 is formed by depositing a titanium film (about 500 Angstroms thickness), an aluminum film (about 3,000 Angstroms thickness), and a titanium film (about 500 Angstroms thickness), or the like in that order on the entire substrate where the first gate insulation film 12a has been formed in the aforementioned first gate insulation film formation process. Thereafter, photolithography is used to pattern the second metal film 13 so that part of each source line 11a is exposed from the first gate insulation film 12a, and a plurality of gate lines 13a are formed to have a through hole Ha arranged at the exposed part of each source line 11a. Here, in the gate line formation process, the second metal film 13 is patterned such that the inner face of each through hole Ha is tilted by 40° to 50° relative to the surface of the insulating substrate 10 so that each through hole Ha becomes progressively larger outwardly with increasing distance from the surface of the insulating substrate 10. Specifically, for example, by reflow through heat treatment or the like of a resist pattern formed on the second metal film 13, the resist pattern can be formed such that the side wall becomes gently sloping. Thereafter, the resultant resist pattern can be used for isotropic etching to form a forward tapered shape (40° to 50°).

Second Gate Insulation Film Formation Process

As shown in FIG. 3(d), a second insulation film 14 is formed, for example, by deposition of silicon nitride (1,500 Angstroms thickness) or the like by the plasma CVD method on the entire substrate upon which the multiple gate lines 13a had been formed in the aforementioned gate line formation process. Thereafter, photolithography is used to pattern the second insulation film 14 such that at the interior of each through hole Ha of each gate line 13a, at least part of the respective source line 11a that has been exposed from the first gate insulation film 12a is exposed, thereby forming the second gate insulation film 14a.

Semiconductor Layer Formation Process

First, for example, an ion doping method is used for phosphorus doping of the part exposed from the second gate insulation film 14a of each source line 11a of the substrate upon which the second gate insulation film 14a has been formed in the aforementioned second gate insulation film formation process.

Thereafter, as shown in FIG. 4(a), a semiconductor film 15 is formed, for example, by depositing an intrinsic amorphous silicon film (7,000 Angstroms thickness) or the like by the plasma CVD method on the entire aforementioned phosphorus-doped substrate. Thereafter, photolithography is used to pattern the semiconductor film 15 such that at the interior of each through hole Ha of each gate line 13a, the semiconductor formation layer 15a is formed.

Furthermore, for example, phosphorus doping by an ion doping method is used to dope the semiconductor formation layer 15a of the substrate onto which the semiconductor layer formation layer 15a has been formed. Thereafter, heating is used to form a semiconductor layer 15a provided with N+ amorphous silicon layers 15aa and 15ac and an intrinsic amorphous silicon layer 15ab.

Drain Electrode Formation Process

As shown in FIG. 4(b), a third metal film 16 is formed, for example, by depositing a titanium film (about 500 Angstroms thick) and an aluminum film (about 3,000 Angstroms thick), or the like in that order by the sputtering method on the entire substrate upon which the semiconductor layer 15a has been formed in the aforementioned semiconductor layer formation process. Thereafter, photolithography is used to pattern the third metal film 16 such that a plurality of drain electrodes 16a are formed so as to overlay the semiconductor layer 15a.

Pixel Electrode Formation Process

As shown in FIG. 4(c), a transparent electrically conductive film 17 is formed, for example, by deposition of an ITO film (indium tin oxide, about 1,000 Angstroms thick) by the sputtering method on the entire substrate upon which a plurality of drain electrodes 16a have been formed in the aforementioned drain electrode formation process. Thereafter, photolithography is used to pattern the transparent electrically conductive film 17 such that a plurality of pixel electrodes 17a are formed so as to overlap the respective drain electrodes 16a.

Finally, after a printing method is used to coat a polyimide resin on the entire substrate upon which a plurality of pixel electrodes 17a have been formed, an alignment film is formed by conducting a rubbing treatment on the polyimide resin.

The TFT substrate 20 of the present embodiment may be manufactured in the aforementioned manner.

As described above, according to the TFT substrate 20 of the present embodiment and the manufacturing method thereof, the first gate insulation film process forms the first gate insulation film 12a for electrical insulation of each source line 11a formed in the source line formation process and each gate line 13a formed in the gate line formation process. During the gate line formation process, a plurality of gate lines 13a are formed so that each has a through hole Ha at the intersection with the respective source line 11a formed in the source line formation process. During the second gate insulation film formation process, the second gate insulation film 14a is formed to electrically insulate the drain electrode 16a to be formed in the drain electrode process, the semiconductor layer 15a to be formed in the semiconductor layer formation process, and each gate line 13a formed in the gate line formation process. During the semiconductor layer formation process, a semiconductor layer 15a is formed so as to be connected to the respective source line 11a that has been formed during in source line formation process. During drain electrode formation, the drain electrode 16a is formed to connect the semiconductor layer 15a formed in the semiconductor layer formation process to the respective pixel electrode 17a formed in the pixel electrode formation process. Therefore, a semiconductor layer 15a is provided at the interior of each through hole Ha of each gate line 13a with a second gate insulation film 14a interposed therebetween, one end of the respective semiconductor layer 15a exposed from the respective gate line 13a contacts the respective source line 11a, the other end contacts the drain electrode 16a connected to a respective pixel electrode 17a, and therefore, in the TFT 5a thus manufactured, the channel electrical current flows in the direction in which the respective through hole Ha of each gate line 13a extends—i.e., in the thickness direction of the substrate. Also, in this TFT 5a, in surface directions of the insulating substrate 10 (i.e., along the direction of the surface), the semiconductor layer 15a is surrounded by the inner faces of the through hole Ha of the gate line 13a (formed of a metal that blocks light). Also, in the thickness direction of the insulating substrate 10, the source line 11a and the drain electrode 16a (formed of a metal that blocks light) overlap the semiconductor layer 15a, and thus light from the backlight or the like hardly enters the semiconductor layer 15a. Therefore, it becomes possible to suppress the light-induced increase of off-state current of the TFT by use of the TFT substrate 20 having TFT 5a at each intersection of the source lines 11a and the gate lines 13a.

In the TFT substrate 20 of the present embodiment, since the TFT 5a is formed at the intersection of each source line 11a and each gate line 13a so as not to extend beyond the source line 11a and the gate line 13a, it is possible to improve the aperture ratio of the pixels.

According to the TFT substrate 20 of the present embodiment, even though the inner face of each through hole Ha is tilted relative to the surface of the insulating substrate 10 such that each through hole Ha becomes progressively larger outwardly with increasing distance from the surface of the insulating substrate 10, the peripheral edges of the drain electrode 16a (made of a metal that blocks light) protrude farther beyond the edges of the respective through hole Ha of the gate line 13a on the side of the drain electrode 16a, and therefore, it is possible to make it difficult for light from the backlight or the like to enter the semiconductor layer 15a.

### Second Embodiment of the Invention

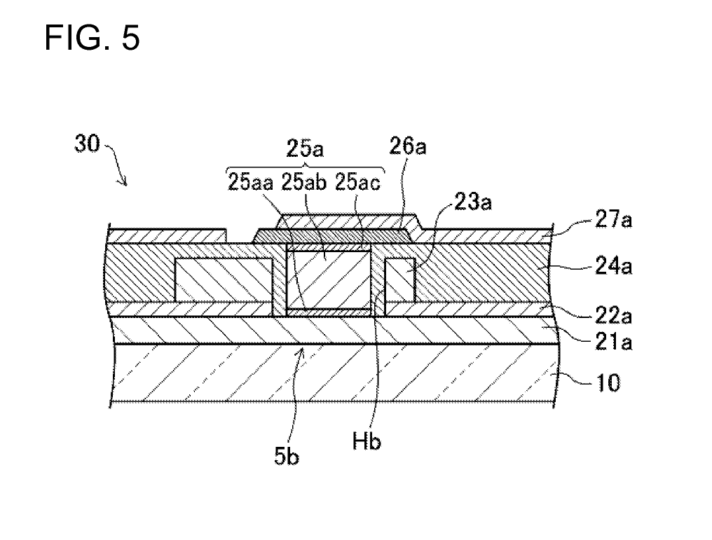

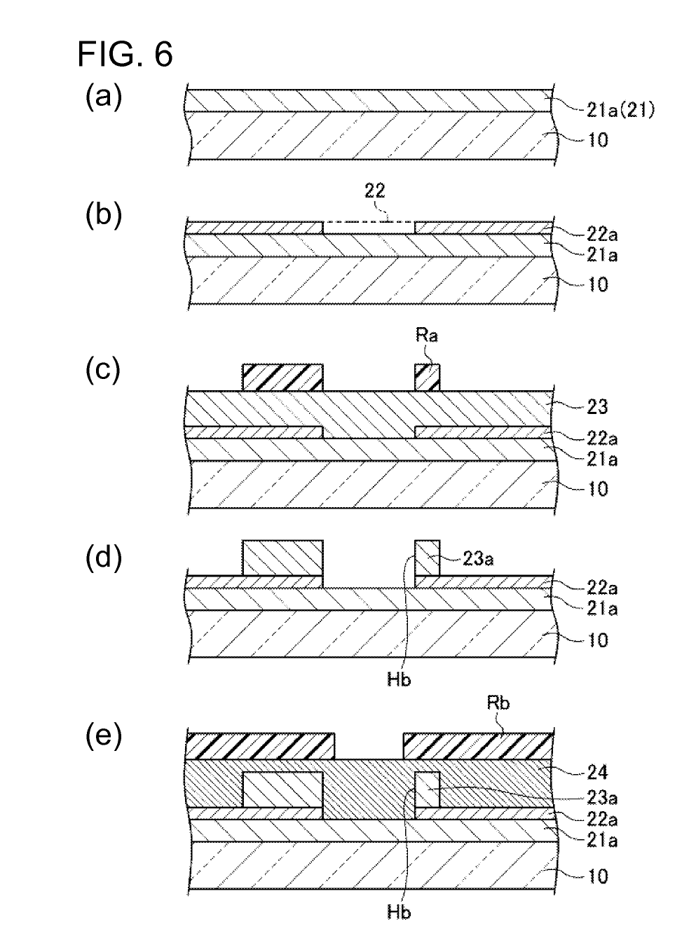

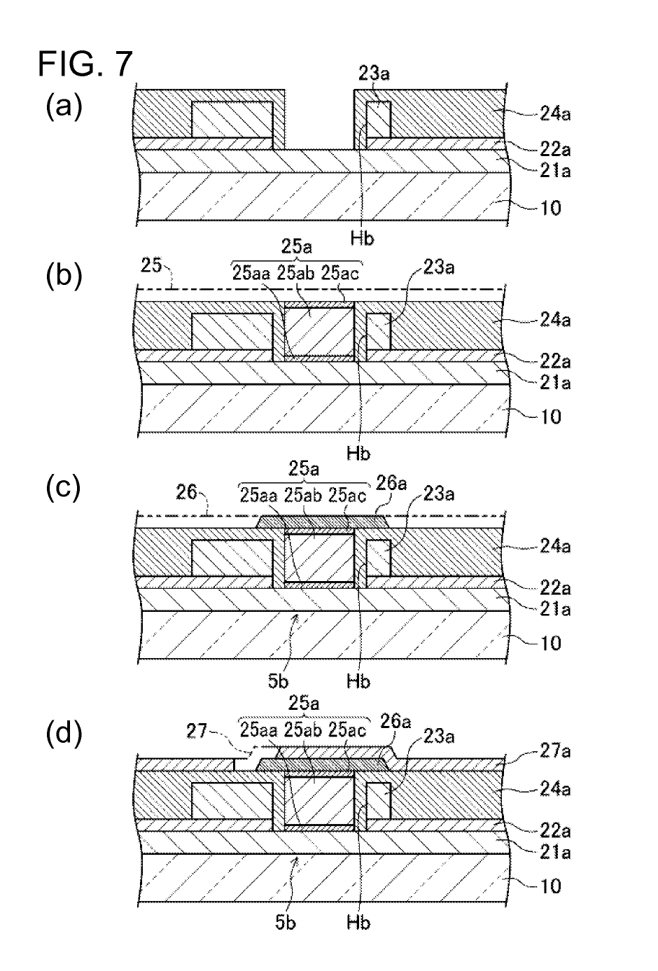

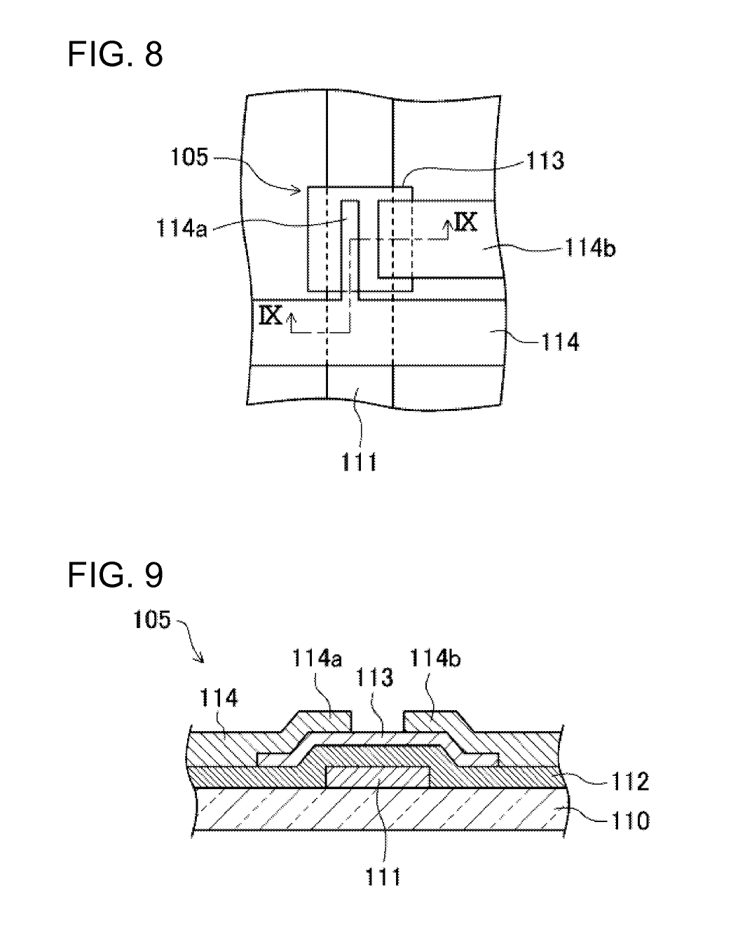

FIGS. 5 to 7 show a second embodiment, and show a thin film transistor substrate and a manufacturing method therefor. Specifically, FIG. 5 is a cross-sectional drawing, comparable to FIG. 2, of the TFT substrate 30 of the present embodiment. Moreover, FIGS. 6 and 7 are cross-sectional drawings showing the manufacturing process of the TFT substrate 30 shown in FIG. 5.

As shown in FIG. 5, the TFT substrate 30 is provided with: an insulating substrate 10, a plurality of source lines 21a arranged so as to extend parallel to one another on the insulating substrate 10, a plurality of gate lines 23a arranged so as to extend parallel to one another in a direction that intersects each of the source lines 21a, a plurality of TFTs 5b that are each arranged at a respective intersection of each source line 21a and each gate line 23a, a plurality of pixel electrodes 27a that are each connected to a respective TFT 5b and that are provided in a matrix pattern extending along the direction of extension of each source line 21a and the direction of extension of each gate line 23a, and an alignment film (not illustrated) arranged so as to cover each pixel electrode 27a.

The gate line 23a, as shown in FIG. 5, has a through hole Hb that penetrates in the thickness direction of the insulating substrate 10 at the intersection with the respective source lines 21a. Here, the through hole Hb, as shown in FIG. 5, has an inner face that is perpendicular to the surface of the insulating substrate 10. Furthermore, the through hole Hb of the present embodiment has a circular shape as viewed from above in a manner similar to that of the aforementioned first embodiment. However, this shape is exemplary, and the shape as viewed from above may be polygonal or elliptical.

As shown in FIG. 5, the TFT 5b is provided with a cylindrically-shaped gate electrode (23a) that is an interior face part of each respective through hole Hb of the gate line 23a, a first gate insulation film 22a that electrically insulates between the source line 21a and the gate line (gate electrode) 23a, a second gate insulation film 24a arranged so as to cover the gate electrode (23a), a semiconductor layer 25a provided in the interior of each respective through hole Hb (i.e., in the concave part of the second gate insulation film 24a), a source electrode (21a) that is part of the source line 21a connected to one end (downward end in the figure) of the semiconductor layer 25a exposed from the gate line (gate electrode) 23a, and a drain electrode 26a connected to the other end (upper end in the figure) of the semiconductor layer 25a exposed from the gate line (gate electrode 23a).

As shown in FIG. 5, the semiconductor layer 25a includes an N+ amorphous silicon layer 25aa connected to the source line (source electrode) 21a, an N+ amorphous silicon layer 25ac connected to the drain electrode 26a, and an intrinsic amorphous silicon layer 25ab provided between the N+ amorphous silicon layer 25aa and the N+ amorphous silicon layer 25ac.

As shown in FIG. 5, the source line (source electrode) 21a is disposed so as to overlap the semiconductor layer 25a.

As shown in FIG. 5, the drain electrode 26 is disposed so as to overlap the semiconductor layer 25a. Moreover, as shown in FIG. 5, the pixel electrode 27a is disposed on the drain electrode 26a.

The TFT substrate 30 of the aforementioned structure constitutes an active matrix drive type liquid crystal display together with a CF substrate (not illustrated) disposed facing the TFT substrate 30 and a liquid crystal layer (not illustrated) sealed between these substrates.

Next, a method of manufacture of the TFT substrate 30 of the present embodiment will be described with reference to FIGS. 6 and 7. The method of manufacture of the present invention includes a source line formation process, a first gate insulation film formation process, a gate line formation process, a second gate insulation film formation process, a semiconductor layer formation process, a drain electrode formation process, and a pixel electrode formation process.

Source Line Formation Process

As shown in FIG. 6(a), the sputtering method, for example, is used to form a metal film 21 by depositing a titanium film (about 500 Angstroms thick) and an aluminum film (about 3,000 Angstroms thick), or the like in that order on the entire insulating substrate 10 substrate (i.e., glass substrate or the like). Thereafter, photolithography is used to pattern the first metal film 21 to form a plurality of source lines 21a. A method of directly forming each source line 21a on the insulation substrate 10 is used as an example in the present embodiment, although a base coat film may be formed between the insulating substrate 10 and each source line 21a.

First Gate Insulation Film Formation Process

As shown in FIG. 6(b), by the plasma chemical vapor deposition (CVD), for example, a first insulation film 22 of silicon nitride (about 1,500 Angstroms thickness) or the like is formed on the entire substrate onto which the multiple source lines 21a have been formed in the aforementioned source line formation process. Thereafter, photolithography is used to form the first gate insulation film 22a by patterning the first insulation film 22 so that at least part of the (anticipated) intersection between each source line 21a and each gate line 23a is exposed.

Gate Line Formation Process

First, as shown in FIG. 6(c), by a sputtering method, for example, a second metal film 23 is formed by depositing a titanium film (about 500 Angstroms thickness), an aluminum film (about 3,000 Angstroms thickness), and a titanium film (about 500 Angstroms thickness), or the like in that order on the entire substrate where the first gate insulation film 22a has been formed in the aforementioned first gate insulation film formation process. Thereafter, the first resist pattern Ra is formed on the second metal film 23.

Thereafter as shown in FIG. 6(d), the second metal film 23 exposed from the first resist pattern Ra is etched to form a plurality of gate lines 23a in which a through hole Hb is formed at the exposed part of each source line 21a. Thereafter, the first resist pattern Ra is removed. Here, in the gate line formation process, the second metal film 23 is patterned such that the inner face of each through hole Hb is perpendicular to the surface of the insulating substrate 10.

Second Gate Insulation Film Formation Process

First, as shown in FIG. 6(e), a second insulation film 24 (e.g., silicon nitride, about 7,000 Angstroms thick, or the like) formed by the plasma CVD method is deposited on the entire substrate, upon which a plurality of gate lines 23a have been formed in aforementioned gate line formation process, so as to bury each through hole Hb of each gate line 23a. Thereafter, the second resist pattern Rb is formed on the second insulation film 24.

Thereafter, as shown in FIG. 7(a), the second insulation film 24 exposed from the second resist pattern Rb is etched so as to the expose a part of source line 21a that has been exposed from the first gate insulation film 22a within each through hole Hb of each gate line 23a, thereby forming the second gate insulation film 24a. Thereafter, the second resist pattern Rb is removed.

Semiconductor Layer Formation Process

First, with respect to the substrate upon which the second gate insulation film 24a has been formed in the aforementioned second gate insulation film formation process, an ion doping method is used, for example, for phosphorus doping onto the part of the source line 21a that has been exposed from the second gate insulation film 24a.

Thereafter, as shown in FIG. 7(b), the semiconductor film 25 is formed, for example, by deposition of an intrinsic amorphous silicon film (7,000 Angstroms thickness) or the like by the plasma CVD method on the entire aforementioned phosphorus-doped substrate. Thereafter, photolithography is used to pattern the semiconductor film 25 such that, at the interior of each through hole Hb of each gate line 23a, the semiconductor layer formation layer 25a is formed.

Furthermore, for example, phosphorus doping by the ion doping method is used to dope the semiconductor layer formation layer 25a of the substrate onto which had been formed the semiconductor layer formation layer 25a. Thereafter, heating is used to form a semiconductor layer 25a provided with N+ amorphous silicon layers 25aa and 25ac and an intrinsic amorphous silicon layer 25ab.

Drain Electrode Formation Process

As shown in FIG. 7(c), a third metal film 26 is formed, for example, by depositing a titanium film (about 500 Angstroms thick) and an aluminum film (about 3,000 Angstroms thick), or the like in that order by the sputtering method on the entire substrate upon which the semiconductor layer 25a has been formed in the aforementioned semiconductor layer formation process. Thereafter, photolithography is used to pattern the third metal film 26 such that a plurality of drain electrodes 26a are formed so as to overlay the semiconductor layer 25a.

Pixel Electrode Formation Process

As shown in FIG. 7(d), a transparent electrically conductive film 27 is formed, for example, by deposition of an ITO film (about 1,000 Angstroms thick) by the sputtering method on the entire substrate upon which a plurality of drain electrodes 26a have been formed in the aforementioned drain electrode formation process. Thereafter, photolithography is used to pattern the transparent electrically conductive film 27 to form a plurality of pixel electrodes 27a to overlap the respective drain electrodes 26a.

Finally, after a printing method is used to coat a polyimide resin on the entire substrate upon which had been formed the multiple pixel electrodes 27a, an alignment film is formed by conducting a rubbing treatment on the polyimide resin.

The TFT substrate 30 of the present embodiment can be manufactured in the aforementioned manner.

As described above, according to the TFT substrate 30 of the present embodiment and the manufacturing method thereof, the first gate insulation film process forms the first gate insulation film 22a for electrical insulation between each source line 21a formed in the source line formation process and each gate line 23a formed in the gate line formation process. In the gate line formation process, a plurality of gate lines 23a having a through hole Hb at the intersection with the respective source line 21a formed in the source line formation process are formed. During the second gate insulation film formation process, the second gate insulation film 24a is formed to electrically insulate the drain electrode 26a to be formed in the drain electrode process, the semiconductor layer 25a to be formed during the semiconductor layer formation process, and the gate line 23a formed in the gate line formation process. In the semiconductor layer formation process, a semiconductor layer 25a is formed so as to be connected to the source line 21a that has been formed in the source line formation process. In the drain electrode formation, the drain electrode 26a is formed to connect the semiconductor layer 25a formed in the semiconductor layer formation process to the respective pixel electrode 27a to be formed in the pixel electrode formation process. Therefore, a semiconductor layer 25a is provided at the interior of each through hole Hb of each gate line 21a with a second gate insulation film 24a interposed therebetween, one end of each semiconductor layer 25a exposed from a respective gate line 23a contacts a respective source line 21a, the other end contacts a drain electrode 26a connected to a respective pixel electrode 27a so that in the TFT 5b thus manufactured, the channel electrical current flows in the direction of extension of each through hole Hb of each gate line 23a—i.e., in the thickness direction of the substrate. Also, in this TFT 5b, in the surface directions of the insulating substrate 10 (i.e., along the direction of the surface), the semiconductor layer 25a is surrounded by the inner faces of the through hole Hb of the gate line 23a (formed of a metal that blocks light). Also, in the thickness direction of the insulating substrate 10, the source line 21a and the drain electrode 26a (formed of a metal that blocks light) overlap the semiconductor layer 25a, and thus light from the backlight or the like hardly enters the semiconductor layer 25a. Therefore, in the TFT substrate 30 in which the TFT 5b is provided at the respective intersection of each source line 21a and each gate line 23a, it is possible to suppress the light-induced increase of off-state current of the TFT.

In the TFT substrate 30 of the present embodiment, since the TFT 5b is formed at the intersection of each source line 21a and each gate line 23a so as not to extent beyond the source line 21a and the gate line 23a, it is possible to improve the aperture ratio of the pixels.

According to the TFT substrate 30 of the present embodiment, because the inner face of each through hole Hb of each gate line 23a is perpendicular to the surface of the insulating substrate 10, compared with the case as in the aforementioned first embodiment where the inner face of each through hole Ha is tilted relative to the surface of the insulating substrate 10, it is possible to reduce the size of the TFT 5b, and it is possible to further improve the aperture ratio of the pixels.

### INDUSTRIAL APPLICABILITY

As explained above, the present invention enables suppression of the light-induced increase of off-state current of the TFT, and the present invention is thus useful for a TFT substrate constituting a liquid crystal display panel.

### Description of Reference Characters

Ha, Hb through hole
5a, 5b TFT
10 insulating substrate
11, 21 first metal film
11a, 21a source line
12, 22 first insulation film
12a, 22a first gate insulation film
13, 23 second metal film
13a, 23a gate line
14, 24 second insulation film
14a, 24a second gate insulation film
15, 25 semiconductor film
15a, 25a semiconductor layer
16, 26 third metal film
16a, 26a drain electrode
17, 27 transparent electrically conductive film
17a, 27a pixel electrode
20, 30 TFT substrate

1. A thin film transistor substrate comprising:
a plurality of source lines disposed to extend parallel to a substrate;
a plurality of gate lines disposed to extend in parallel with each other in a direction that intersects said source lines; and
a plurality of pixel electrodes arranged in a matrix along said direction of extension of said source lines and along said direction of extension of said gate lines,
wherein in each of said gate lines, a through hole is provided at an intersection part with each source line so as to penetrate the gate line in a direction of thickness of said substrate,
wherein a semiconductor layer is provided on an interior of each of said through hole of the gate line with a gate insulation film interposed therebetween, and
wherein one end of each of the semiconductor layers is overlapped by and connected to the corresponding source line, and the other end thereof is overlapped by and is connected to a drain electrode electrically connected to corresponding said pixel electrode.

2. The thin film transistor according to claim 1, wherein an inner face of each said through hole is sloped so that the through hole becomes progressively larger outwardly with increasing distance from a surface of said substrate.

3. The thin film transistor substrate according to claim 2, wherein the angle of the inner face of said through hole relative to the surface of said substrate is 40° to 50°.

4. The thin film transistor substrate according to claim 2, wherein a peripheral edge of said drain electrode extends beyond an edge of said through hole in said gate line on a side of said drain electrode.

5. The thin film transistor substrate according to claim 1, wherein an inner face of each said through hole is perpendicular to a surface of said substrate.

6. A method for manufacturing a thin film transistor substrate that comprises:
a plurality of source lines disposed to extend in parallel with each other;
a plurality of gate lines disposed to extend parallel to each other in a direction that intersects said source lines; and
a plurality of pixel electrodes disposed in a matrix along said direction of extension of said source lines and along said direction of extension of said gate lines,
the method comprising:
a source line formation process that includes forming a first metal film on said substrate and thereafter patterning said first metal film to form said plurality of source lines;
a first gate insulation film formation process that includes forming a first insulation film so as to cover each source line formed in said source line formation process, and thereafter patterning said first insulation film so as to expose at least part of said intersection of the source line and the gate line to form a first gate insulation film;
a gate line formation process that includes forming a second metal film to cover said first gate insulation film formed in said first gate insulation film formation process, and thereafter patterning said second metal film so as to expose a part of the said source line that has been exposed from said first gate insulation film to form said plurality of gate lines having a through hole arranged in said exposed part of each said source line;
a second gate insulation film formation process that includes forming a second insulation film to cover said gate line formed in said gate line formation process, and thereafter patterning said second insulation film so as to expose at least a part of said exposed part of said source line within an interior of said through hole of each said gate line to form a second gate insulation film;
a semiconductor layer formation process that includes forming a semiconductor film so as to cover said second gate insulation film formed in said second gate insulation film formation process, and thereafter patterning said semiconductor film to form a semiconductor layer in the interior of each through hole of each said gate line;
a drain electrode formation process that includes forming a third metal film so as to cover each said semiconductor layer formed in said semiconductor layer formation process, and thereafter patterning said third metal film to form a plurality of drain electrodes so as to overlap corresponding said semiconductor layer; and
a pixel electrode formation process that includes forming a transparent electrically conductive film so as to cover each said drain electrode formed in said drain electrode formation process, and thereafter patterning said transparent electrically conductive film to form said plurality of pixel electrodes so as to overlap corresponding said drain electrode.

7. The method for manufacturing a thin film transistor substrate according to claim 6, wherein, in said gate line formation process, said second metal film is patterned so that an inner face of each said through hole is tilted relative to a surface of said substrate so that each said through hole becomes progressively larger outwardly with increasing distance from the surface of said substrate.

8. The method for manufacturing a thin film substrate according to claim 6,
wherein, in said gate line formation process, said second metal film is patterned so that an inner face of each said through hole is perpendicular to a surface of said substrate, and
wherein, in said second gate insulation film formation process, after forming said second insulation film so as to bury each through hole of each said gate line, said second insulation film is patterned.
